(19) United States
(12) Patent Application Publication
(10) Pub. No.: US 2025/0015519 A1
(43) Pub. Date: Jan. 9, 2025

(54) PRINTED CIRCUIT BOARD CONNECTOR WITH DETECTIBLE SHAPED ELEMENT

(71) Applicant: HARTING Electronics GmbH, Espelkamp (DE)

(72) Inventors: Gert HAVERMANN, Wallenhorst (DE); Jana BUSCHMANN, Rahden (DE)

(21) Appl. No.: 18/712,413

(22) PCT Filed: Dec. 9, 2022
(86) PCT No.: PCT/DE2022/100929

§ 371 Date: May 22, 2024

(30) Foreign Application Priority Data
Dec. 22, 2021 (DE) 10 2021 134 344.5

(51) Int. Cl. H01R 12/70; H01R 12/71; H01R 13/46; H01R 13/502; H01R 13/6581

(52) U.S. Cl. CPC H01R 12/7052; H01R 12/712; H01R 13/465; H01R 13/502; H01R 13/6581

(57) ABSTRACT

A printed circuit board connector with a housing for accommodating at least one contact element, the housing having at least one holding element for connection to a printed circuit board. The housing has at least one shaped element and the shaped element is designed such that it can be detected by at least one sensor element.

The invention is based on a printed circuit board connector according to the preamble of independent claim 1. For improved use of automated component applicator devices, it is proposed to attach a detectable shaped element to the housing of the printed circuit board connector.

Such printed circuit board connectors are required in order to connect printed circuit boards to at least one further printed circuit board and/or to a cable. In order to equip printed circuit boards with components, such as chips, resistors and/or printed circuit board connectors, automated component applicator devices are used.

### PRIOR ART

The prior art discloses very many printed circuit board connectors. Conventionally, they are available in dark colors. This entails the problem that the housings of the printed circuit board connectors, which are conventionally configured in one color, are difficult to detect. Optical sensors in particular, for example cameras, do not register the fundamentally fine contours and in particular holding elements such as socket pins, positioning pins, encoding pins or similar elements of a printed circuit board connector, or register them only unsatisfactorily.

The German Patent and Trade Mark Office has searched the following prior art in the priority application for the present application: DE 10 2007 038 221 B3, DE 102 36 114 A1 and DE 693 09 761 T2.

### OBJECT

The object of the invention is to provide a printed circuit board connector which, in particular, can be received reliably and precisely by automated component applicator devices and can likewise be placed reliably and precisely on a printed circuit board.

The object is achieved by the subject matter of independent claim 1.

Advantageous configurations of the invention are specified in the dependent claims and the following description.

The object is achieved by a printed circuit board connector having a housing for receiving at least one contact element, the housing having at least one holding element for connection to a printed circuit board. The housing has at least one shaped element, the shaped element being configured in such a way that it can be registered by at least one sensor element. The printed circuit board connector is thus configured according to the invention with an element that can be identified particularly simply and reliably by sensor systems. According to the invention, the shaped element is configured as part of the housing. Alternatively, the shaped element may be added to the housing. A particularly simple geometrical shape and/or partial shape is suitable as a shaped element for this application. Triangles are found to be particularly effective. The shaped element may likewise be configured as a polygon. The shaped element may be configured as a semicircle or sector of a circle. The shaped element may be configured as a three-sided prism. The shaped element may be configured as a many-sided prism. The shaped element may be configured as a partially cylindrical element. Other shapes may have a comparable, well-identifiable effect, or the effect that it can be registered by sensor systems, and may therefore conceivably be used.

According to a further embodiment of the invention, the shaped element merges substantially into the base shape of the housing. This means that the shaped element extends flush with the planes and/or sides and/or edges of the housing. This ensures that, particularly when the printed circuit board connector is being automatically fitted to a printed circuit board, precise and clean positioning is achieved.

According to one further developed embodiment, the shaped element is arranged next to a holding element. A holding element means, in particular, an element that improves and/or reinforces the connection of the printed circuit board connector to the printed circuit board. In particular,

In one expedient embodiment, the shaped element is highlighted by a contrast element on the housing. A contrast element means, in particular, an element that makes the shaped element more clearly identifiable by sensor elements. Alternatively, a marking distinguishable by color from the shaped element may be used as a contrast element. A shaped element may therefore be detected more easily even by relatively old and/or weak sensors. A component application process may be improved even further and made even more precise in this way.

In one embodiment, the contrast element is configured substantially as a contrast shape, which is arranged on the housing. For example, an edge, a face or a mirrored shaped element is suitable as a contrast shape.

In an alternative embodiment, the housing is formed from at least a housing front and a housing back, the housing front being connected to the housing back. This means, in particular, that a housing is configured in at least two parts. Alternatively, the housing front may be referred to as the first housing element. The housing back may therefore be referred to as the second housing element. In one embodiment, the housing front is materially bonded to the housing back. Alternatively, the housing front is connected to the housing back with a form fit. Alternatively, the housing front is connected to the housing back with a force fit.

In one embodiment, the housing front differs detectably from the housing back. This means, in particular, optical discrimination of the housing front from the housing back. Thus, the housing front may have a first color while the housing back has a second color, the first color differing from the second color. Alternatively, the housing front and/or housing back may be formed from plastics having a different metal element density, or a housing front does not have any metal elements in its composition while the housing back has a defined proportion of metal elements, or vice versa. Alternatively, a housing front may also have a different surface structure than a housing back.

In another embodiment, the shaped element has at least one detectable marking. A detectable marking means, in particular, an optically identifiable difference on or in the shaped element. Here, a feature distinguishable by color seems to be particularly advantageous. The shaped element may in this case be formed from a material differing in color from the housing. Alternatively, color printing may suitably be used. Printing that at least for the most part follows the shape of the shaped element seems to be particularly expedient in this case. In other words, an arrowhead-like and/or triangular shaped element may be improved by a triangular marking arranged in this triangular shape so that it is easily identifiable. Simple adhesive labels that can be distinguished optically from the housing may suitably be used.

In one embodiment, the shaped element is at least partially enclosed by at least one detectable marking. This means that the shaped element is at least partially bordered by, for example, printed and/or integrally formed and/or adhesively bonded markings, and is therefore highlighted so that it can be identified better.

In one embodiment, the housing is configured to receive at least one shielding element. A particularly positive property is thereby provided for a printed circuit board connector in relation to possible electromagnetic interference and/or signal crosstalk. A shielding element consisting of an electrically conductive metal may furthermore conceivably be used to demarcate a shaped element more clearly identifiably from the housing.

One embodiment therefore proposes that the shaped element is attached to the housing in such a way that the shielding element acts as a detectable contrast element. For example, the shaped element is attached to an element that is intended to receive a shielding element. This receiving element of the shielding element expediently protrudes outward away from the housing of the printed circuit board connector and/or beyond the shielding element, so that a shaped element can readily be identified from the outside by sensors.

In one embodiment, the housing is configured so that it can be correspondingly brought into engagement with a substantially identically constructed housing. This means that the printed circuit board connector is configured with a so-called “hermaphrodite” housing. Such housings are particularly advantageous since essentially only one tool needs to be used for manufacture for the purpose of producing a printed circuit board connector and a corresponding printed circuit board mating connector. For use, such printed circuit board connectors essentially offer the advantage of reduced stock keeping for repair purposes and/or servicing purposes, since different types of printed circuit board connector do not need to be stocked.

In one embodiment, the contact element is configured so that it can be correspondingly brought into engagement with a substantially identically constructed contact element. The use of such contact elements is suitable in particular for a printed circuit board connector with a hermaphrodite housing, since the printed circuit board connector its housing

### EXEMPLARY EMBODIMENT

An exemplary embodiment of the invention is represented in the drawings and will be explained in more detail below.

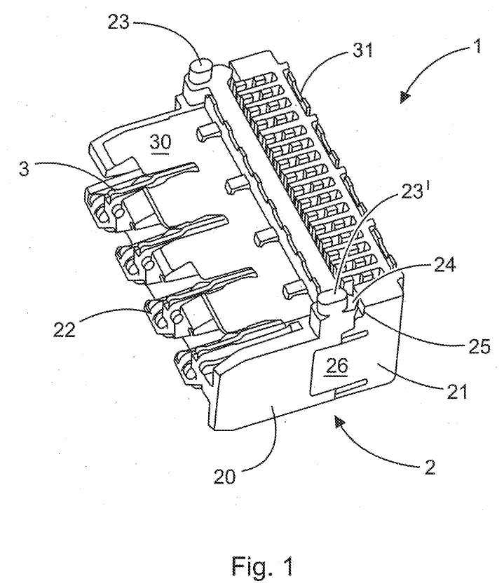

FIG. 1 shows a perspective representation of a printed circuit board connector according to the invention;

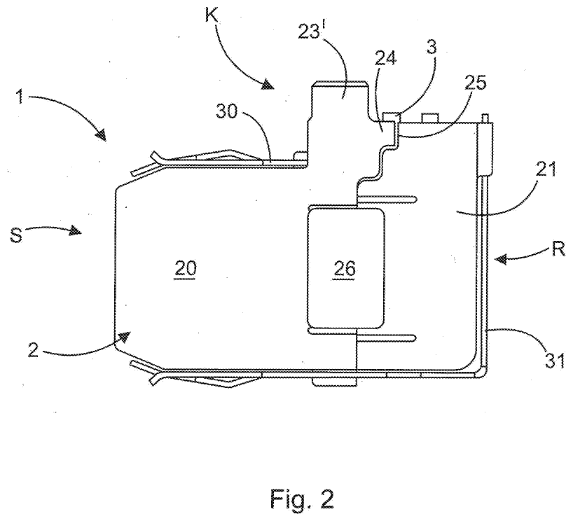

FIG. 2 shows a side view of a printed circuit board connector according to the invention;

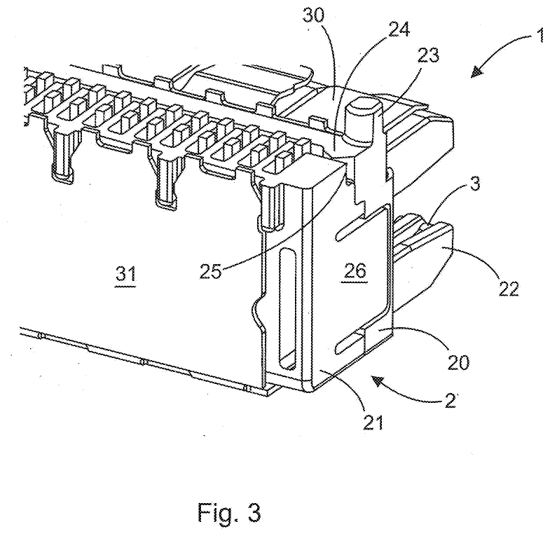

FIG. 3 shows a first detail view of a printed circuit board connector according to the invention;

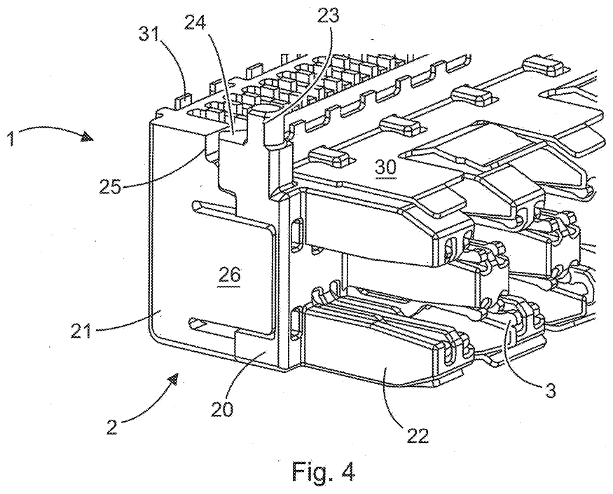

FIG. 4 shows a second perspective detail view of a printed circuit board connector according to the invention.

The figures contain partially simplified schematic representations. Identical reference signs are sometimes used for elements which are equivalent but possibly not identical. Different views of the same elements may be scaled differently. Direction indications, for example “left”, “right”, “up” and “down”, are to be understood with reference to the figure in question, and may vary in relation to the object represented in the individual representations.

FIG. 1 shows an embodiment of an electrical printed circuit board connector 1 according to the invention, configured as an angled printed circuit board connector, in a perspective representation with a view of the side to be connected to a printed circuit board. To simplify the terminology, this side will be described below as the board side K. The board side K thus means the side on which the holding elements 23 and 23′ as well as the shaped elements 24 according to the invention are located. The printed circuit board connector 1 is configured with electrical contact elements 3, which are inserted into contact sockets 22. The printed circuit board connector 1 shown has a housing 2, which is in turn formed from two housing elements. A first housing element, which will be referred to below as the housing front 20, is used in the plug region of the plug side S. The housing back 21 is connected thereto by a housing connection 26. As implied by its name, the housing back 21 is arranged on the rear side R of the printed circuit board connector 1. For unique positioning on the printed circuit board (not represented), the housing 2 has two mutually different holding elements 23 and 23′. Shaped elements 24 according to the invention are located in the immediate vicinity of these holding elements 23 and 23′. These shaped elements 24 are prismatically shaped and act as arrows which onto a contrast element 25 configured as a housing edge of the housing back 21. In order to protect against electromagnetic perturbations, the printed circuit board connector 1 has two shielding elements 30 and 31.

FIG. 2 shows a similar design of the described printed circuit board connector 1, configured as an angled printed circuit board connector, in a side view. Arrows indicate various sides of the housing 2. This makes it clearer where a plug side S, the rear side R and the board side K are located according to the description. In contrast to FIG. 1, FIG. 2 two shows an embodiment in which the housing front 20 is connected to the housing back 21 by a separate housing connection 26. It is furthermore shown that the contact elements 3 are aligned substantially flush with one another in a plane on the board side K. The shielding elements 30 and 31 also terminate substantially in the same plane, FIG. 2 showing only the end of the shielding element 31 on the board side.

FIG. 3 shows a perspective view of the printed circuit board connector 1 in a view of the board side S from the rear side R. It is in this case clear from a rear viewing angle that a shaped element 24 according to the invention enables optical detection from many viewing angles.

This positive effect may likewise be seen in FIG. 4. The housing 2 formed from the housing back 21 and the housing front 20 has a contrast element 25 formed as an edge of the housing back 21, which clearly identifiably emphasizes by the arrow-like shaped element 24. This means of position identification is particularly advantageously improved when a color difference is introduced into the housing 2. In other words, the invention proposes to produce and/or coat the housing front 20 in a first color. The housing back 21 is consequently produced and/or coated in a second color, the first color differing at least detectably from the second color. Particularly high-contrast differences seem to be particularly advantageous in this case. High-contrast differences, for example black and white, can ensure that even optical sensors without an RGB spectrum achieve the desired position identification on the housing 2. It is also conceivable to use the (ideally uncoated) shielding elements as contrast elements in this case.

### LIST OF REFERENCE SIGNS

1 printed circuit board connector
2 housing
20 housing front
21 housing back
22 contact socket
23 holding element
24 shaped element
25 contrast element
26 housing connection
3 contact element
30 shielding element
31 shielding element
S plug side
R rear side
K board side

1: A printed circuit board connector having a housing for receiving at least one contact element, the housing having at least one holding element for connection to a printed circuit board,
wherein
the housing has at least one shaped element, the shaped element being configured in such a way that it can be registered by at least one sensor element.

2: The printed circuit board connector as claimed in claim 1, wherein
the shaped element merges substantially into the base shape of the housing.

3: The printed circuit board connector as claimed in claim 1, wherein
the shaped element is arranged next to a holding element.

4: The printed circuit board connector as claimed in claim 1, wherein
the shaped element is highlighted by a contrast element on the housing.

5: The printed circuit board connector as claimed in claim 1, wherein
the contrast element is configured substantially as a contrast shape, the contrast shape being arranged on the housing.

6: The printed circuit board connector as claimed in claim 1, wherein
the housing is formed from at least a housing front and a housing back, the housing front being connected to the housing back.

7: The printed circuit board connector as claimed in claim 1, wherein
the housing front differs detectably from the housing back.

8: The printed circuit board connector as claimed in claim 1, wherein
the shaped element has at least one detectable marking.

9: The printed circuit board connector as claimed in claim 1, wherein
the shaped element is at least partially enclosed by at least one detectable marking.

10: The printed circuit board connector as claimed in claim 1, wherein
the housing is configured to receive at least one shielding element.

11: The printed circuit board connector as claimed in claim 1, wherein
the shaped element is attached to the housing in such a way that the shielding element acts as a detectable contrast element.

12: The printed circuit board connector as claimed in claim 1, wherein
the shaped element is attached to an element that is intended to receive a shielding element.

13: The printed circuit board connector as claimed in claim 1, wherein
the housing is configured so that it can be correspondingly brought into engagement with a substantially identically constructed housing.

14: The printed circuit board connector as claimed in claim 1, wherein
the contact element is configured so that it can be correspondingly brought into engagement with a substantially identically constructed contact element.

15: The printed circuit board connector as claimed in claim 2, wherein
the shaped element is arranged next to a holding element.

16: The printed circuit board connector as claimed in claim 2, wherein
the shaped element is highlighted by a contrast element on the housing.

17: The printed circuit board connector as claimed in claim 2, wherein
the contrast element is configured substantially as a contrast shape, the contrast shape being arranged on the housing.

18: The printed circuit board connector as claimed in claim 2, wherein
the housing is formed from at least a housing front and a housing back, the housing front being connected to the housing back.

19: The printed circuit board connector as claimed in claim 2, wherein
the housing front differs detectably from the housing back.

20: The printed circuit board connector as claimed in claim 2, wherein
the shaped element has at least one detectable marking.
